(19) United States
(12) Patent Application Publication
(10) Pub. No.: US 2017/0194548 A1
(43) Pub. Date: Jul. 6, 2017

(54) SEMICONDUCTOR DEVICE

(71) Applicant: FUJITSU LIMITED, Kawasaki-shi (JP)

(72) Inventor: Yukiko Wakino, Sagamihara (JP)

(73) Assignee: FUJITSU LIMITED, Kawasaki-shi (JP)

(21) Appl. No.: 15/369,963

(22) Filed: Dec. 6, 2016

(30) Foreign Application Priority Data
Jan. 5, 2016 (JP) 2016-000600

(51) Int. Cl. H01L 35/30; H01L 35/10; H01L 35/32

(52) U.S. Cl. CPC H01L 35/30; H01L 35/32; H01L 35/10

(57) ABSTRACT

A semiconductor device includes: a board; an electronic element mounted over the board; a Peltier element placed over the electronic element; a first holding board placed over the Peltier element; a radiation member placed over the first holding board; and a first thermal conduction layer placed between the first holding board and the radiation member, the first thermal conduction layer being in close contact with the first holding board.

### CROSS-REFERENCE TO RELATED APPLICATION

This application is based upon and claims the benefit of priority of the prior Japanese Patent Application No. 2016-000600, filed on Jan. 5, 2016, the entire contents of which are incorporated herein by reference.

### FIELD

The embodiments discussed herein are related to a semiconductor device.

### BACKGROUND

A semiconductor device including a heat generation part mounted on a circuit board (for example, a central processing unit (CPU)) may need to have an excellent heat radiation property in terms of, for example, reliability. Thus, there are known a semiconductor device including a heat generation part that is connected to a heat sink via a Peltier element, and a semiconductor device including a heat generation part that is connected to a radiator having radiation fins via a liquid heat sink. In addition, there is known a cooling unit including a heat transfer plate that is connected to a cooler device via an expanded graphite foil and a Peltier element.

When a heat generation part is mounted on a circuit board, bending occurs in the heat generation part due to a difference in coefficient of thermal expansion between the circuit board and the heat generation part. In a configuration in which a Peltier element and a radiator are provided on the heat generation part, the heat generated from the heat generation part may be hardly conducted to the radiator due to the influence of the bending of the heat generation part.

The followings are reference documents.

### [Document 1] Japanese Laid-Open Patent Publication No. 2010-140194,

### [Document 2] Japanese Laid-Open Patent Publication No. 04-284654, and

### [Document 3] Japanese Laid-Open Patent Publication No. 2015-060846.

### SUMMARY

According to an aspect of the invention, a semiconductor device includes: a board; an electronic element mounted over the board; a Peltier element placed over the electronic element; a first holding board placed over the Peltier element; a radiation member placed over the first holding board; and a first thermal conduction layer placed between the first holding board and the radiation member, the first thermal conduction layer being in close contact with the first holding board.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view illustrating a semiconductor device according to Comparative Example 1;

FIG. 2 is a sectional view illustrating a semiconductor device according to Example 1;

FIGS. 3A to 3C are sectional views illustrating a method of manufacturing the semiconductor device according to Example 1;

FIGS. 4A to 4C are sectional views illustrating a method of manufacturing the semiconductor device according to Example 1;

FIG. 5 is a sectional view illustrating a semiconductor device according to Comparative Example 2;

FIG. 6 is a sectional view illustrating a semiconductor device according to Example 2;

FIGS. 7A to 7D are sectional views illustrating a method of manufacturing the semiconductor device according to Example 2; and

FIGS. 8A to 8D are sectional views illustrating a method of manufacturing the semiconductor device according to Example 2.

### DESCRIPTION OF EMBODIMENTS

Hereinafter, examples of the present disclosure will be described with reference to the accompanying drawings.

### Example 1

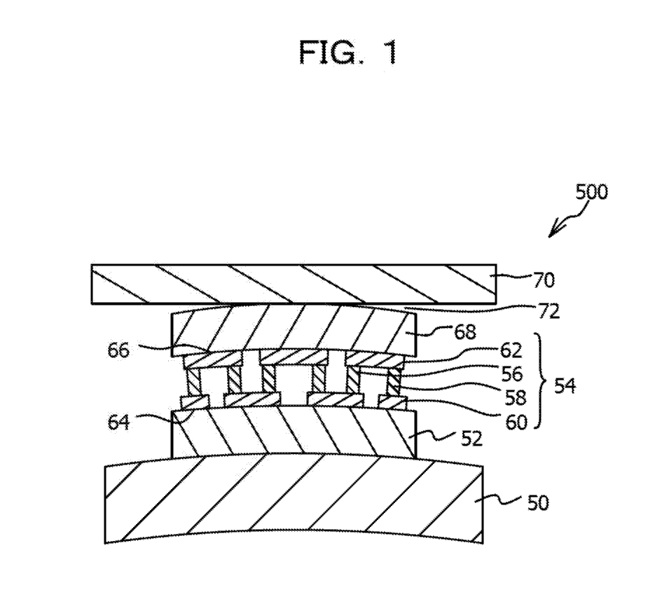

First, a semiconductor device according to Comparative Example 1 will be described. FIG. 1 is a sectional view illustrating a semiconductor device 500 according to Comparative Example 1. As illustrated in FIG. 1, the semiconductor device 500 of Comparative Example 1 includes a central processing unit (CPU) 52 that is mounted on a circuit board 50 via, for example, reflow soldering. The circuit board 50 is formed as a member of an organic material such as, for example, glass epoxy, and the CPU 52 is formed of, for example, silicon (Si). The coefficient of thermal expansion of glass epoxy is 40 ppm/K, and the coefficient of thermal expansion of Si is 4.6 ppm/K. Thus, because a difference in coefficient of thermal expansion between the circuit board 50 and the CPU 52 is large, when the CPU 52 is reflow-soldered on the circuit board 50 at a relatively high temperature, and then the CPU 52 and the circuit board 50 return to a room temperature, bending occurs in the circuit board 50 and the CPU 52. For example, the circuit board 50 and the CPU 52 become a convexly bent shape.

A Peltier element 54 is provided on the CPU 52. The Peltier element 54 includes P-type semiconductors 56 and N-type semiconductors 58, which are alternately arranged, and also includes metal electrodes 60 and 62 with the P-type semiconductors 56 and the N-type semiconductors 58 being interposed therebetween. The bottom surface of each metal electrode 60 becomes a heat absorption surface 64 that absorbs heat, and the top surface of the metal electrode 62 becomes a heat radiation surface 66 that radiates the heat absorbed by the heat absorption surface 64 by the Peltier effect. The heat absorption surfaces 64 of the plural metal electrodes 60 are in close contact with the CPU 52. Therefore, the Peltier element 54 is formed into a convexly bent shape under the influence of bending of the CPU 52.

A ceramic board 68 is provided to be in close contact with the heat radiation surfaces 66 of the metal electrodes 62. The ceramic board 68 is formed of, for example, aluminum nitride (AlN). The ceramic board 68 is in close contact with the plural metal electrodes 62. Therefore, the ceramic board 68 is formed into a convexly bent shape under the influence of bending of the Peltier element 54.

A radiator (heat sink) 70 is provided on the ceramic board 68. Because the bottom surface of the radiator 70 has a flat shape and the top surface of the ceramic board 68 has a convex bent shape, a gap 72 is formed between the ceramic board 68 and the radiator 70.

In this way, in the semiconductor device 500 of Comparative Example 1, the gap 72 is formed between the ceramic board 68 and the radiator 70. Therefore, the heat generated from the CPU 52 is hardly transferred to the radiator 70. Thereby, the temperature of the CPU 52 increases, causing an operation failure or breakage of the CPU 52, which may deteriorate reliability. In addition, because the elastic modulus of the ceramic board 68 is relatively high (the elastic modulus of AlN is 320 GPa), the ceramic board 68 has a risk of being broken by stress according to the bending. When cracks are formed in the ceramic board 68, the conduction of heat generated from the CPU 52 to the radiator 70 further deteriorates.

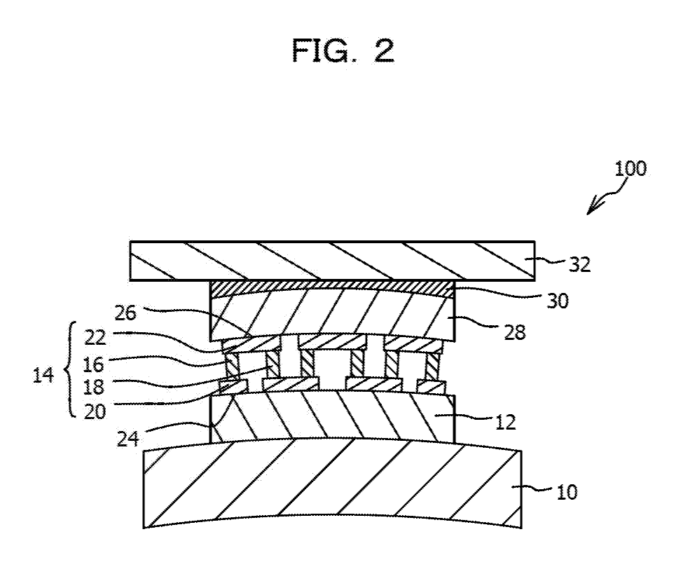

FIG. 2 is a sectional view illustrating a semiconductor device 100 according to Example 1. As illustrated in FIG. 2, in the semiconductor device 100 of Example 1, a central processing unit (CPU) 12 is mounted on a circuit board 10 via, for example, reflow soldering of a ball grid array (BGA). The thickness of the circuit board 10 is, for example, 2 mm, and the thickness of the CPU 12 is, for example, 0.5 mm. The circuit board 10 is formed as a member of an organic material, such as, for example, glass epoxy, and the CPU 12 is formed of, for example, Si. Therefore, in the same manner as the semiconductor device 500 of Comparative Example 1, the circuit board 10 and the CPU 12 become a convexly bent shape due to a difference in coefficient of thermal expansion between the circuit board 10 and the CPU 12. The bent amount of the CPU 12 after the reflow is, for example, about 130 μm at a room temperature (e.g., 25° C.), and is, for example, about 110 μm at a temperature of 80° C. The bent amount of the circuit board 10 after the reflow is, for example, about 240 μm at a room temperature (e.g., 25° C.), and is, for example, about 200 μm at a temperature of 80° C.

A Peltier element 14 is provided on the CPU 12. The Peltier element 14 includes P-type semiconductors 16 and N-type semiconductors 18, which are alternately arranged, and also includes metal electrodes 20 and 22 with the P-type semiconductors 16 and the N-type semiconductors 18 being interposed therebetween. The metal electrodes 20 and 22 are formed of, for example, copper (Cu). The bottom surface of the metal electrode 20 becomes a heat absorption surface 24 that absorbs heat, and the top surface of the metal electrode 22 becomes a heat radiation surface 26 that radiates the heat absorbed by the heat absorption surface 24 by the Peltier effect. The heat absorption surface 24 absorbs heat generated from the CPU 12. The heat radiation surface 26 radiates the absorbed heat generated from the CPU 12 by the Peltier effect.

The heat absorption surface 24 of the metal electrode 20 is in close contact with the top surface of the CPU 12. Because each of the plural metal electrodes 20 has a small area, each metal electrode 20 is in close contact with the top surface of the CPU 12 corresponding to the bending of the CPU 12. For example, all of the plural metal electrodes 20 are in close contact with the top surface of the CPU 12. Because the plural metal electrodes 20 are in close contact with the top surface of the CPU 12, the Peltier element 14 becomes a convexly bent shape under the influence of bending of the CPU 12.

A holding board 28, which is, for example, aluminum nitride (AlN) ceramic board, is provided on the Peltier element 14. The holding board 28 is in close contact with the heat radiation surfaces 26 of the plural metal electrodes 22. For example, the holding board 28 is in close contact with all of the plural metal electrodes 22. Because the holding board 28 is in close contact with the plural metal electrodes 22, it becomes easy to control the holding board 28 compared to the case where the plural metal electrodes 22 are separated. In addition, when a material having excellent thermal conductivity, such as aluminum nitride, is used in the holding board 28, further heat radiation to a radiator 32 is enabled. The thickness of the holding board 28 is, for example, 1.5 mm. Because the holding board 28 is in close contact with the heat radiation surfaces 26 of the plural metal electrodes 22, the holding board 28 is formed into a convexly bent shape under the influence of bending of the Peltier element 14.

A thermal conduction layer 30 is held on the holding board 28. The bottom surface of the thermal conduction layer 30 is in close contact with the top surface of the holding board 28 to have a shape corresponding to the convex bending of the holding board 28. The top surface of the thermal conduction layer 30 has a flat shape. The thermal conduction layer 30 is formed of, for example, expanded graphite. The thickness of the thermal conduction layer 30 is, for example, 0.2 mm in the vicinity of the central portion thereof and is, for example, 0.33 mm in the vicinity of the end portion thereof.

The radiator (heat sink) 32 is provided on the thermal conduction layer 30. The radiator 32 serves to further radiate heat radiated from the heat radiation surface 26 of the Peltier element 14. The bottom surface of the radiator 32 has a flat shape. The bottom surface of the thermal conduction layer 30 provided between the holding board 28 and the radiator 32 has a bent shape corresponding to the convex bending of the holding board 28, and the top surface of the thermal conduction layer 30 has a flat shape. Therefore, the formation of a gap between the holding board 28 and the radiator 32 is suppressed.

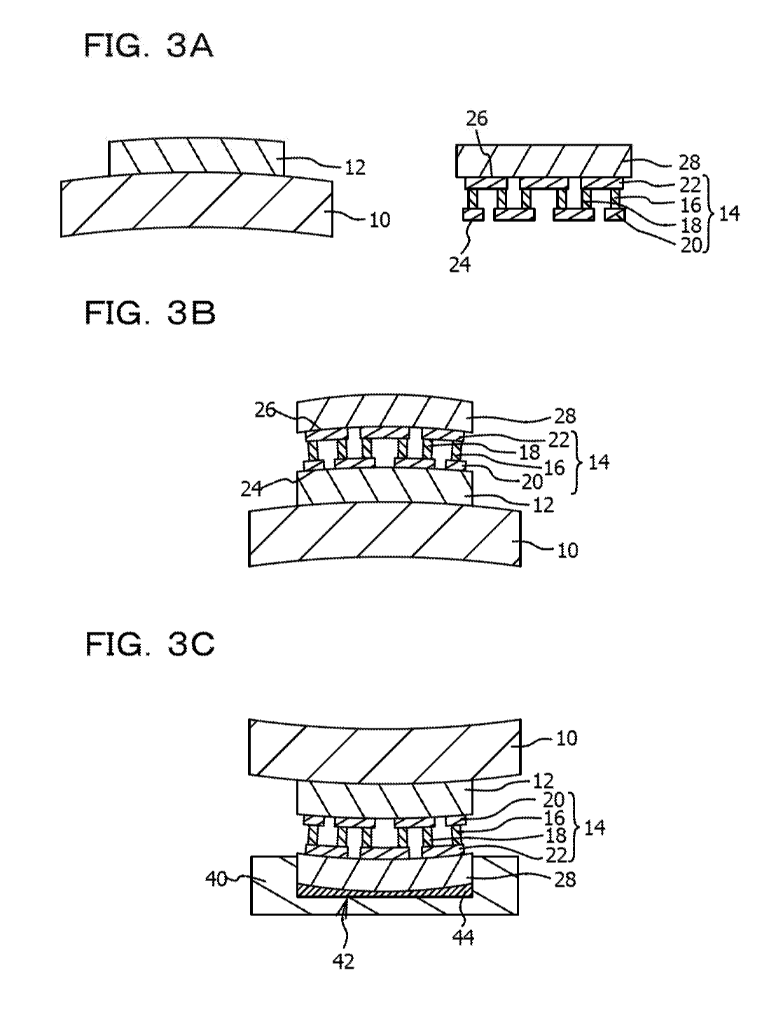

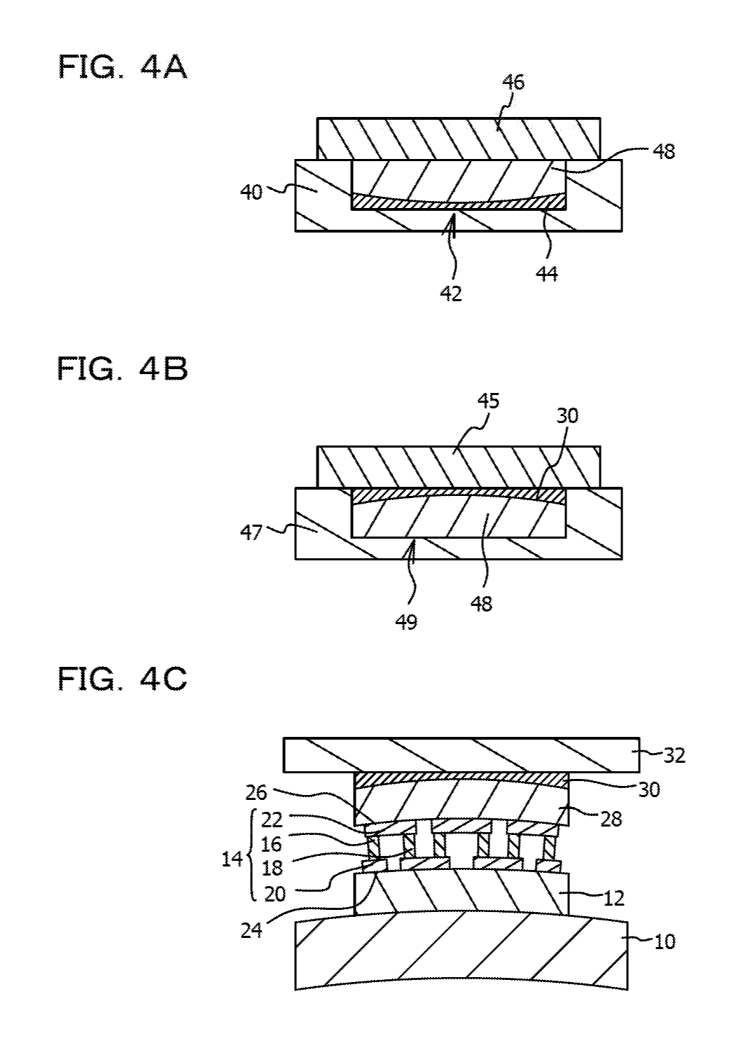

Next, a method of manufacturing the semiconductor device 100 according to Example 1 will be described. FIGS. 3A to 4C are sectional views illustrating the method of manufacturing the semiconductor device 100 according to Example 1. As illustrated in FIG. 3A, the CPU 12 is mounted on the circuit board 10 via, for example, reflow soldering. After mounting the CPU 12, as described above, convex bending occurs in the circuit board 10 and the CPU 12. Simultaneously with the mounting of the CPU 12 on the circuit board 10, a member is prepared in which the holding board 28 is bonded to the heat radiation surface 26 of the Peltier element 14. The holding board 28 is formed of, for example AlN, and the metal electrode 22 of the Peltier element 14 is formed of, for example, Cu. Therefore, because a difference in coefficient of thermal expansion between the holding board 28 and the metal electrode 22 is not so large (the coefficient of thermal expansion of AlN is 4.6 ppm/K and the coefficient of thermal expansion of Cu is 16.5 ppm/K), the occurrence of bending is suppressed. That is, the holding board 28 and the Peltier element 14 have an almost flat shape.

As illustrated in FIG. 3B, the heat absorption surface 24 of the Peltier element 14 is bonded to the CPU 12. As described above, because each of the plural metal electrodes 22 has a small area, the plural metal electrodes 20 are bonded to the CPU 12 corresponding to bending of the CPU 12. Thereby, the Peltier element 14 and the holding board 28 are formed into a convexly bent shape under the influence of bending of the CPU 12.

As illustrated in FIG. 3C, a molten raw material of a mold (e.g. plastic) is introduced into a recess 42 provided in a frame 40, and then, the top surface of the holding board 28 is pushed against the raw material of the mold. Thereby, a transfer mold 44, which reflects the bent shape of the holding board 28, is formed.

As illustrated in FIG. 4A, after the molten raw material of the mold is introduced into the recess 42 having the transfer mold 44 formed therein, a push plate 46 is pushed from the top side. Thereby, a mold 48, which has the same shape as the bent shape of the holding board 28, is formed. In addition, when a release agent is previously applied to the surface of the transfer mold 44 or the side surface of the recess 42, the mold 48 is able to be easily separated from the recess 42.

As illustrated in FIG. 4B, after the mold 48 is installed in a recess 49 provided in a Thomson mold 47, an expanded graphite sheet is pressed into the mold 48 side using a reinforcement plate 45. Because a Thomson blade is installed in the recess 49, the expanded graphite sheet is cut to a desired size. Thereby, the thermal conduction layer 30 is formed, of which the bottom surface has a shape depending on the bending of the holding board 28, and the top surface is flat.

As illustrated in FIG. 4C, the bottom surface of the thermal conduction layer 30 is bonded to the top surface of the holding board 28 using, for example, a conductive adhesive. Because the bottom surface of the thermal conduction layer 30 has a shape depending on the bending of the holding board 28, the holding board 28 and the thermal conduction layer 30 are bonded to each other without a gap therebetween. Thereafter, the bottom surface of the radiator 32 is bonded to the top surface of the thermal conduction layer 30 using, for example, a conductive adhesive. Because both the top surface of the thermal conduction layer 30 and the bottom surface of the radiator 32 have a flat shape, the thermal conduction layer 30 and the radiator 32 are bonded to each other without a gap therebetween. According to the process described above, the semiconductor device 100 of Example 1 may be formed.

According to Example 1, the thermal conduction layer 30, which conducts heat radiated by the heat radiation surface 26 of the Peltier element 14 to the radiator 32, is held with the holding board 28 which is in close contact with the heat radiation surface 26 of the Peltier device unit 14. That is, the thermal conduction layer 30 is provided between the holding board 28 and the radiator 32. Thereby, because the formation of a gap between the holding board 28 and the radiator 32 is able to be suppressed, the heat from the CPU 12 is able to be efficiently conducted to the radiator 32. In consideration of the efficient conduction of the heat from the CPU 12 to the radiator 32, the bottom surface of the thermal conduction layer 30 may be in close contact with the holding board 28, thus being formed into a bent shape corresponding to the bending of the holding board 28, and the top surface of the thermal conduction layer 30 may be in close contact with the bottom surface of the radiator 32, thus being formed into a flat shape.

In addition, according to Example 1, the heat absorption surface 24 of the metal electrode 20 is in close contact with the CPU 12. As described above, because each of the metal electrodes 20 has a small area, the plural metal electrodes 20 may be in close contact with the CPU 12 in response to bending of the CPU 12. In addition, even if the bent amount of the CPU 12 varies due to a variation in temperature depending on, for example, the operation of the CPU 12, the metal electrodes 20 is able to follow the variation in the bending of the CPU 12. Accordingly, the heat from the CPU 12 is able to be efficiently conducted to the Peltier element 14.

In addition, according to Example 1, the bottom surface of the thermal conduction layer 30 is in close contact with the entire top surface of the holding board 28. Therefore, the heat from the CPU 12 is able to be efficiently conducted to the radiator 32. In addition, because the entire top surface of the thermal conduction layer 30 is in close contact with the radiator 32, the heat from the CPU 12 is also able to be efficiently conducted to the radiator 32 in this sense.

In addition, according to Example 1, the thermal conduction layer 30 is formed of expanded graphite. Because expanded graphite has a relatively low elastic modulus (the elastic modulus of expanded graphite is 13.5 GPa), even if the amount of bending of the holding board 28 varies due to variation in temperature depending on, for example, the operation of the CPU 12, the thermal conduction layer 30 may follow variation in the bending of the holding board 28. Accordingly, formation of a gap between the holding board 28 and the radiator 32 is able to be suppressed. In addition, when the thermal conduction layer 30 follows variation in the bending of the holding board 28, stress attributable to the bending applied to the holding board 28 is able to be alleviated, which may suppress breakage of the holding board 28.

As described above, the thermal conduction layer 30 may be formed as a member having a relatively low elastic modulus, and may be formed as a member, which may follow variation in the amount of bending of the holding board 28 depending on variation in temperature. For example, the thermal conduction layer 30 may be formed of artificial graphite having an elastic modulus in a range of 9.8 GPa to 16.8 GPa. The thermal conduction layer 30 may be formed as a member having an elastic modulus lower than that of the holding board 28 (the elastic modulus of AlN is 320 GPa). The thermal conduction layer 30 may be formed as a member having a modulus of elasticity, which may be ⅕ or less, and specifically 1/10 or less the modulus of elasticity of the holding board 28.

In addition, because the heat generated from the CPU 12 is conducted to the radiator 32 via the thermal conduction layer 30, the thermal conduction layer 30 may be formed as a member having a relatively high thermal conductivity. Expanded graphite and artificial graphite have a relatively high thermal conductivity (the thermal conductivity of expanded graphite: 139 W/m·K and the thermal conductivity of artificial graphite: 100 W/m·K to 250 W/m·K), and therefore, are suitable even in this sense. The thermal conduction layer 30 may be formed as a member, the thermal conductivity of which may be 50% or more, specifically 60% or more, and more specifically 70% or more the thermal conductivity of the holding board 28 (the thermal conductivity of AlN: 150 W/m·K). For example, the thermal conduction layer 30 may have an elastic modulus loser than that of copper (Cu) or aluminum (Al) (the elastic modulus of Cu is 128 GPa, and the elastic modulus of Al is 70 GPa) and also may have a higher thermal conductivity than the thermal conductivity of silicon (0.16 W/m·K).

In addition, in consideration of variation in temperature depending on, for example, operation of the CPU 12, the thermal conduction layer 30 may be formed as a member having approximately the same coefficient of thermal expansion as the holding board 28. The expanded graphite and artificial graphite have approximately the same coefficient of thermal expansion as AlN (the coefficient of thermal expansion of expanded graphite in a surface direction is 4.4 ppm/K, the coefficient of thermal expansion of artificial graphite is 0.3 ppm/K to 1.0 ppm/K, and the coefficient of thermal expansion of AlN is 4.6 ppm/K. Therefore, expanded graphite and artificial graphite are suitable even in this sense. The thermal conduction layer 30 may be formed as a member having a coefficient of thermal expansion, which may be 25% or more and 200% or less, and specifically 50% or more and 150% or less the coefficient of thermal expansion of the holding board 28.

### Example 2

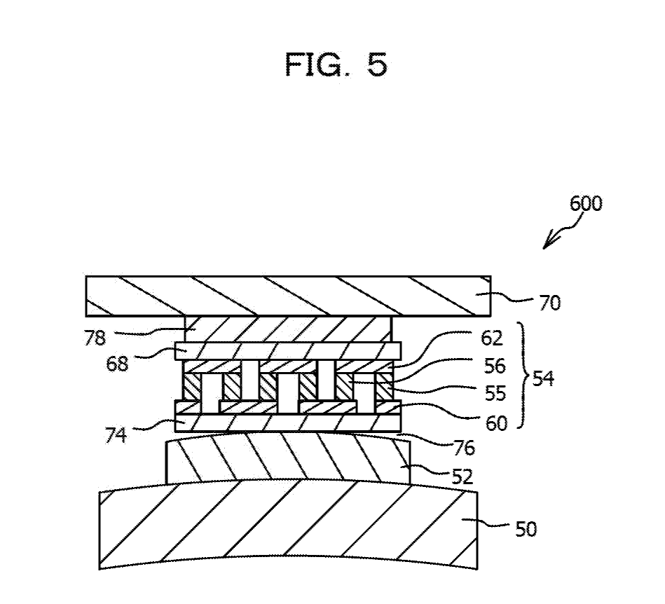

First, a semiconductor device according to Comparative Example 2 will be described. FIG. 5 is a sectional view illustrating a semiconductor device 600 according to Comparative Example 2. As illustrated in FIG. 5, in the same manner as the semiconductor device 500 of Comparative Example 1, in the semiconductor device 600 of Comparative Example 2, the CPU 52 is mounted on the circuit board 50, and the circuit board 50 and the CPU 52 have a convexly bent shape.

The Peltier element 54 is provided on the CPU 52 to be interposed between ceramic boards 74 and 68. The ceramic boards 74 and 68 are formed of, for example, AlN. The metal electrodes 60 and 62 of the Peltier element 54 are formed of, for example, Cu. As described above, because a difference in coefficient of thermal expansion between AlN and Cu is not so large, bending hardly occurs even if the ceramic boards 74 and 68 are bonded to the metal electrodes 60 and 62. That is, the ceramic boards 74 and 68 and the Peltier element 54 have a substantially flat shape. Because the ceramic board 74 is bonded to the plural metal electrodes 60, and thus has a relatively large area, a portion of the ceramic board 74 is not in close contact with the convexly bent CPU 52. Therefore, a gap 76 is formed between the ceramic board 74 and the CPU 52.

A silicon rubber 78 is provided on the ceramic board 68. The silicon rubber 78 is in close contact with the ceramic board 68 to have a flat shape. The radiator 70 is provided on the silicon rubber 78. The radiator 70 is in close contact with the silicon rubber 78.

In the semiconductor device 600 of Comparative Example 2, the gap 76 is formed between the CPU 52 and the ceramic board 74. Therefore, the heat generated from the CPU 52 to the radiator 70 is hardly conducted. Thereby, the temperature of the CPU 52 may increase, causing an operation failure or breakage of the CPU 52, which may deteriorate reliability.

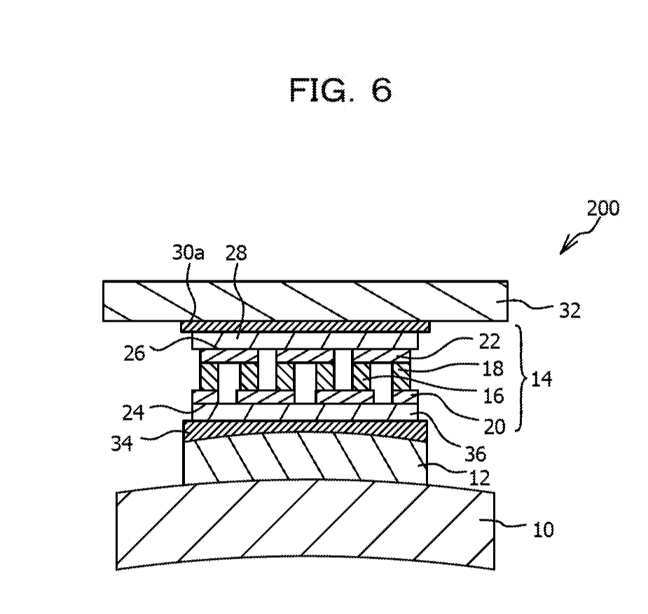

FIG. 6 is a sectional view illustrating a semiconductor device 200 according to Example 2. As illustrated in FIG. 6, in the same manner as the semiconductor device 100 of Example 1, in the semiconductor device 200 of Example 2, the CPU 12 is mounted on the circuit board 10, and the circuit board 10 and the CPU 12 have a convexly bent shape.

A thermal conduction layer 34 is provided on the CPU 12. The bottom surface of the thermal conduction layer 34 is in close contact with the top surface of the CPU 12 to have a shape corresponding to the convex bending of the CPU 12. The top surface of the thermal conduction layer 34 has a flat shape. The thermal conduction layer 34 is formed of, for example, expanded graphite, but may be formed of artificial graphite. The thickness of the thermal conduction layer 34 is, for example, 200 μm in the vicinity of the center portion thereof and is, for example, 330 μm in the vicinity of the end portion thereof.

The Peltier element 14 interposed between holding boards 36 and 28 is provided on the thermal conduction layer 34. Because the plural metal electrodes 20 are bonded to the holding board 36, handling becomes easy compared to the case where the plural metal electrodes 20 are separated. In the same manner, because the plural metal electrodes 22 are bonded to the holding board 28, it becomes easy to handle the plural metal electrodes 22 compared to the case where the plural metal electrodes 22 are separated. The holding boards 36 and 28 are, for example, AlN ceramic boards. The metal electrodes 20 and 22 are formed of, for example, Cu. As described above, because a difference in coefficient of thermal expansion between AlN and Cu is not so large, almost no bending occurs even if the holding boards 36 and 28 are bonded to the metal electrodes 20 and 22. Accordingly, the holding board 36 is in close contact with the flat top surface of the thermal conduction layer 34 without a gap therebetween.

A thermal conduction layer 30a is held on the holding board 28. The bottom surface of the thermal conduction layer 30a is in close contact with the holding board 28 to have a flat shape. The top surface of the thermal conduction layer 30a also has a flat shape. The thermal conduction layer 30a is formed of, for example, expanded graphite, but may be formed of artificial graphite. The thickness of the thermal conduction layer 30a is, for example, 200 μm. The radiator 32 is provided on the thermal conduction layer 30a. Because the top surface of the thermal conduction layer 30a has a flat shape, the radiator 32 is in close contact with the flat top surface of the thermal conduction layer 30a without a gap therebetween.

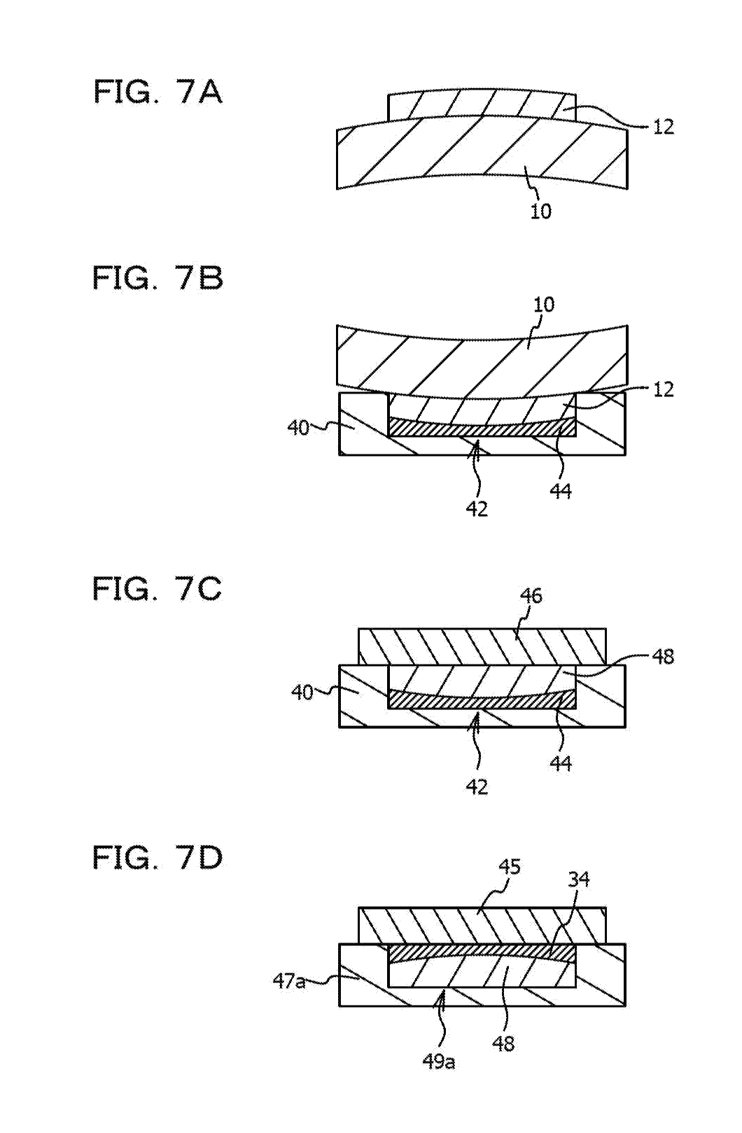

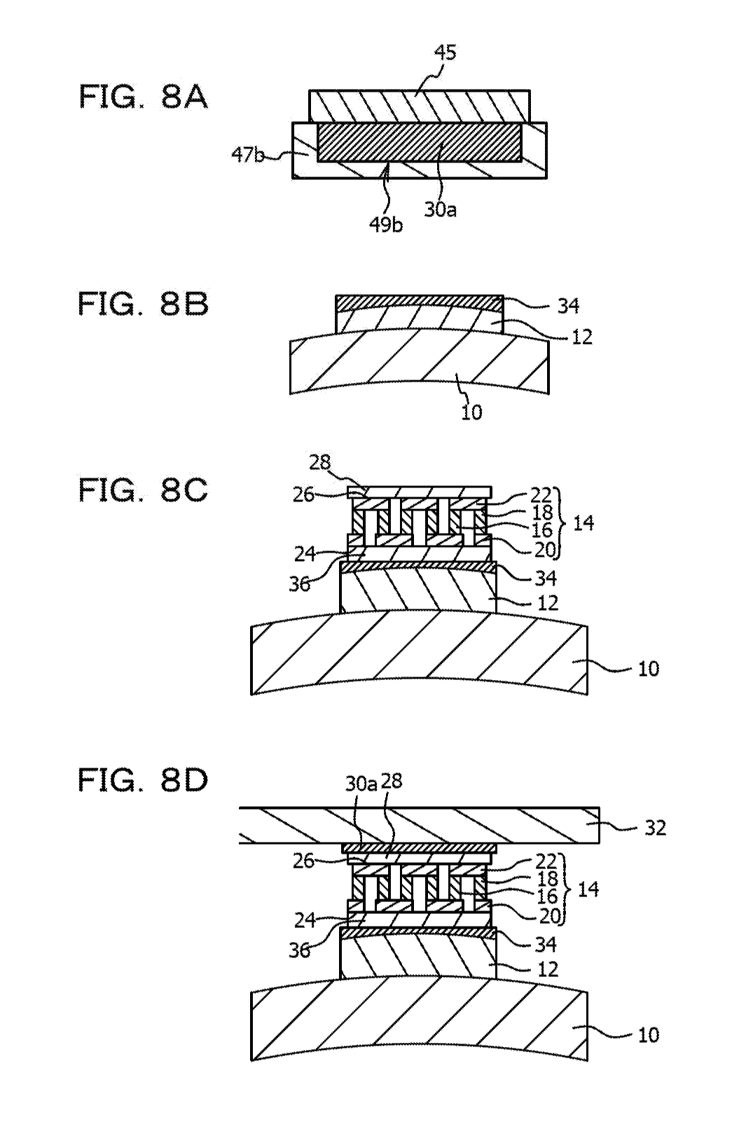

Next, a method of manufacturing the semiconductor device 200 according to Example 2 will be described. FIGS. 7A to 8D are sectional views illustrating a method of manufacturing the semiconductor device 200 according to Example 2. As illustrated in FIG. 7A, the CPU 12 is mounted on the circuit board 10 via, for example reflow soldering. After mounting the CPU 12, as described above, convex bending occurs in the circuit board 10 and the CPU 12.

As illustrated in FIG. 7B, a molten raw material of a mold (e.g. plastic) is introduced into the recess 42 provided in the frame 40, and thereafter, the top surface of the CPU 12 is pushed against the raw material of the mold. Thereby, the transfer mold 44 is formed, which reflects the bent shape of the CPU 12.

As illustrated in FIG. 7C, after the molten raw material of the mold is introduced into the recess 42 having the transfer mold 44 formed therein, the push plate 46 is pushed from the upper side. Thereby, the mold 48, is formed which has the same shape as the bent shape of the CPU 12. In addition, when a release agent is previously applied to the surface of the transfer mold 44 or the side surface of the recess 42, the mold 48 is able to be easily separated from the recess 42.

As illustrated in FIG. 7D, after the mold 48 is installed in the recess 49a provided in a Thomson mold 47a, an expanded graphite sheet is pressed into the mold 48 side using the reinforcement plate 45. Because a Thomson blade is installed in the recess 49a, the expanded graphite sheet is cut into a desired size. Thereby, the thermal conduction layer 34 is formed which includes the bottom surface having a shape depending on the bending of the CPU 12 and the flat top surface.

As illustrated in FIG. 8A, the expanded graphite sheet is pressed into the recess 49b provided in a separate Thomson mold 47b using the reinforcement plate 45. Because a Thomson blade is installed in the recess 49b, the expanded graphite sheet is cut into a desired size. Thereby, the thermal conduction layer 30a is formed, which includes the flat bottom surface and the flat top surface.

As illustrated in FIG. 8B, the bottom surface of the thermal conduction layer 34 is bonded to the top surface of the CPU 12 using, for example, a conductive adhesive. Because the bottom surface of the thermal conduction layer 34 has a shape depending on the bending of the CPU 12, the thermal conduction layer 34 and the CPU 12 are bonded to each other without a gap therebetween.

As illustrated in FIG. 8C, a member is previously prepared in which the top surface of the holding board 36 is bonded to the heat absorption surface 24 of the Peltier element 14 and the bottom surface of the holding board 28 is bonded to the heat radiation surface 26. As described above, because a difference in coefficient of thermal expansion between the holding boards 36 and 28 and the metal electrodes 20 and 22 is not so large, bending hardly occurs even if the holding boards 36 and 28 and the metal electrodes 20 and 22 are bonded to each other. The bottom surface of the holding board 36 is bonded to the top surface of the thermal conduction layer 34 using, for example, a conductive adhesive. Because the top surface of the thermal conduction layer 34 and the bottom surface of the holding board 36 have a flat shape, the thermal conduction layer 34 and the holding board 36 are bonded to each other without a gap therebetween.

As illustrated in FIG. 8D, the bottom surface of the thermal conduction layer 30a is bonded to the top surface of the holding board 28 using, for example, a conductive adhesive. Because both the top surface of the holding board 28 and the bottom surface of the thermal conduction layer 30a have a flat shape, the holding board 28 and the thermal conduction layer 30a are bonded to each other without a gap therebetween. The bottom surface of the radiator 32 is bonded to the top surface of the thermal conduction layer 30a using, for example, a conductive adhesive. Because both the top surface of the thermal conduction layer 30a and the bottom surface of the radiator 32 have a flat shape, the thermal conduction layer 30a and the radiator 32 are bonded to each other without a gap therebetween. According to the process described above, the semiconductor device 200 of Example 2 may be formed.

According to Example 2, the thermal conduction layer 34, which conducts the heat generated from the CPU 12 to the heat absorption surface 24 of the Peltier element 14, is provided between the CPU 12 and the holding board 36, which is in close contact with the heat absorption surface 24 of the Peltier element 14 so as to hold the Peltier element 14. Thereby, because the formation of a gap between the holding board 36 and the CPU 12 is able to be suppressed, heat from the CPU 12 is able to be efficiently conducted to the radiator 32. In consideration of the efficient conduction of heat from the CPU 12 to the radiator 32, the bottom surface of the thermal conduction layer 34 is able to be in close contact with the CPU 12, thus having a bent shape corresponding to the bending of the CPU 12, and the top surface of the thermal conduction layer 34 may come into close contact with the holding board 36, thus having a flat shape.

In addition, according to Example 2, the bottom surface of the thermal conduction layer 30a is in close contact with the entire top surface of the holding board 28, and the top surface of the thermal conduction layer 34 is in close contact with the entire bottom surface of the holding board 36. Therefore, heat from the CPU 12 is able to be efficiently conducted to the radiator 32. In addition, because the entire top surface of the thermal conduction layer 30a is in close contact with the radiator 32 and the bottom surface of the thermal conduction layer 34 is in close contact with the entire top surface of the CPU 12, even in this sense, heat from the CPU 12 is able to be efficiently conducted to the radiator 32.

In addition, according to Example 2, the thermal conduction layer 34 is formed of expanded graphite or artificial graphite. Because expanded graphite and artificial graphite has a relatively low elastic modulus, even if the amount of bending of the CPU 12 varies due to variation in temperature depending on, for example, operation of the CPU 12, the thermal conduction layer 34 may follow variation in the bending of the CPU 12. Accordingly, formation of a gap between the CPU 12 and the holding board 36 is able to be suppressed. In addition, when the thermal conduction layer 34 follows variation in the bending of the CPU 12, stress attributable to bending applied to the CPU 12 may be alleviated, which may suppress breakage of the CPU 12. With regard to this, as a result of calculating stress applied to the CPU in the case where expanded graphite is provided on the CPU (Si), which is mounted on a circuit board (glass epoxy) and in the case where expanded graphite is not provided on the CPU, it has been found that stress applied to the CPU is able to be reduced when expanded graphite is provided. In addition, because the holding boards 28 and 36 and the Peltier element 14 is hardly bent even if the thermal conduction layer 34 follows variation in the bending of the CPU 12, cracks in the holding boards 28 and 36 are hardly formed. As described above, the thermal conduction layer 34 may be formed as a member having a relatively low elastic modulus, and may be formed as a member, which may follow variation in the amount of bending of the CPU 12 depending on variation in temperature. The thermal conduction layer 34 may be formed as a member having an elastic modulus lower than that of the holding board 36. The thermal conduction layer 34 may be formed as a member having an elastic modulus which may be ⅕ or less of the elastic modulus of the holding board 36, and more specifically 1/10 or less of the elastic modulus of the holding board 36.

In addition, because expanded graphite and artificial graphite have a relatively high thermal conductivity, they may efficiently conduct heat generated from the CPU 12. As such, the thermal conduction layer 34 may be formed as a member having a high thermal conductivity. The thermal conduction layer 34 may be formed as a member, the thermal conductivity of which may be 50% or more, specifically 60% or more, and more specifically 70% or more the thermal conductivity of the holding board 36. For example, the thermal conduction layer 34 may have an elastic modulus lower than that of Cu or Al and also may have a higher thermal conductivity than silicon. Here, the amount of heat transfer was calculated in the case where expanded graphite (of which the thermal conductivity is 139 W/m·K) or silicon rubber (of which the thermal conductivity is 1.1 W/m·K) is provided between the CPU 12 and the holding board 36 when the temperature of the CPU 12 is 20° C. The amount of heat transfer may be acquired by Equation: Amount of heat transfer=(Area for Heat Conduction/Thickness of Object)×Thermal Conductivity×Temperature Difference. Here, the calculation was performed under the conditions that Area for Heat Conduction is the size of the CPU 12 (20 mm×20 mm) and Thickness of Object (expanded graphite or silicon rubber) is the amount of bending of the CPU 12 (130 82 m). Based on the result of calculation, the amount of heat transfer is 3.69 W when silicon rubber is used, but is 428 W when expanded graphite is used. Assuming that the amount of heat generated from the CPU 12 is 66 W, it can be found that the amount of heat transfer when expanded graphite is used is sufficiently greater than the amount of heat generated from the CPU 12, and thus, heat generated from the CPU 12 may be efficiently conducted.

In addition, in the same manner as the thermal conduction layer 34, the thermal conduction layer 30a may also be formed as a member having a relatively low elastic modulus and a relatively high thermal conductivity. Accordingly, the thermal conduction layer 30a may be formed of expanded graphite or artificial graphite. Thereby, even if bending occurs in the holding board 28 or the radiator 32 for any reason, formation of a gap between the holding board 28 and the radiator 32 is able to be suppressed, and thus, heat from the CPU 12 is able to be efficiently conducted to the radiator 32.

In addition, although the case where the circuit board 10 and the CPU 12 are convexly bent has been described in Examples 1 and 2 by way of example, they may be concavely bent. In addition, although the case where the CPU 12 is a heat generation part has been described by way of example, any other heat generation part may be used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a board;
an electronic element mounted over the board;
a Peltier element placed over the electronic element;
a first holding board placed over the Peltier element;
a radiation member placed over the first holding board; and
a first thermal conduction layer placed between the first holding board and the radiation member, the first thermal conduction layer being in close contact with the first holding board.

2. The semiconductor device according to claim 1, further comprising:
a second holding board placed between the electronic element and the Peltier element; and
a second thermal conduction layer placed between the electronic element and the second holding board, the second thermal conduction layer being in close contact with the electronic element.

3. The semiconductor device according to claim 2, wherein
the first thermal conduction layer has a bottom surface that is in close contact with the first holding board and has a flat shape, and a top surface that is in close contact with the radiation member to have a flat shape, and
the second thermal conduction layer has a bottom surface that is in close contact with the electronic element to have a bent shape corresponding to bending of the electronic element, and a top surface that is in close contact with the second holding board to have a flat shape.

4. The semiconductor device according to claim 3, wherein
the bottom surface of the first thermal conduction layer is in close contact with the entire top surface of the first holding board, and
the top surface of the second thermal conduction layer is in close contact with the entire bottom surface of the second holding board.

5. The semiconductor device according to claim 2, wherein
the first thermal conduction layer has an entire top surface that is in close contact with the radiation member, and the second thermal conduction layer has a bottom surface that is in close contact with an entire top surface of the electronic element.

6. The semiconductor device according to claim 2, wherein
the first thermal conduction layer has an elastic modulus lower than that of the first holding board, and
the second thermal conduction layer has an elastic modulus lower than that of the second holding board.

7. The semiconductor device according to claim 2, wherein
the first thermal conduction layer and the second thermal conduction layer are formed of expanded graphite or artificial graphite.

8. The semiconductor device according to claim 1, wherein
the Peltier element is in close contact with the electronic element.

9. The semiconductor device according to claim 1, wherein
the circuit board and the electronic element have different coefficients of thermal expansion.
